(19) United States
(12) Patent Application Publication
(10) Pub. No.: US 2009/0235835 A1
(43) Pub. Date: Sep. 24, 2009

(54) Method and apparatus for processing flexographic printing plates

(75) Inventors: Frank A. Hull, East Bethel, MN (US); Roger L. Larson, Shoreview, MN (US); David E. Pitzen, Lino Lakes, MN (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Cortron Corpoation, Minneapolis, MN (US)

(21) Appl. No.: 11/988,582

(22) PCT Filed: Jul. 19, 2006
(86) PCT No.: PCT/US2006/028081

§ 371 Date: Jan. 10, 2008

Related U.S. Application Data
(60) Provisional application No. 60/700,628, filed on Jul. 19, 2005.

(51) Int. Cl. G03F 7/26

(52) U.S. Cl. 101/401.1

(57) ABSTRACT

A flexographic processing system provides a single workstation having a light exposure system for providing exposure of a flexographic plate and a thermal processing system for thermally processing the flexographic plate following exposure. The thermal processing system includes a heated element non-rotationally mounted to a press device that generates pressure between a first surface of the heated element and the flexographic plate. The thermal processing system also includes a material delivery mechanism that delivers absorbent material to the first surface of the heated element, wherein the absorbent material removes uncured photocurable material from the flexographic plate.

### BACKGROUND OF THE INVENTION

The present invention relates to an apparatus and method for exposing, thermally processing, and post-processing a flexographic plate at a single workstation.

Flexographic printing plates are well known for use in printing to a variety of printing surfaces. Flexographic printing plates typically consist of a photocurable material. An image or pattern is created on the flexographic printing plate by exposing select portions of the flexographic plate to a high intensity light, such as that described in U.S. Pat. No. 6,700,598. Exposing the photocurable material to high intensity light causes the cross linking of monomers and/or polymers within the photocurable material, resulting in a cross-linked compound that is more solid than the gel-like photocurable material. By exposing select portions of the photocurable material to high intensity light, a desired image or pattern can be created on the flexographic plate.

A number of steps are required to successfully process a flexographic plate. The first step is to create an image mask corresponding to the desired image. This can be done either digitally or by analog means. The digital method is used on flexographic plates manufactured with a carbon overcoat layer. A laser imaging source is scanned across the flexographic plate, selectively heating and removing the overcoat layer of the flexographic plate to create a mask corresponding to the desired image in a process known as “ablation”. The analog method involves creating a photomask or negative of the image to be plated, known as an image setter, which is then intimately attached to the surface of the flexographic plate.

After creating the image mask, the next step is to expose the flexographic plate (i.e., the unmasked portions of the flexographic plate) to high intensity UV light. The high intensity light cures or cross links the photocurable material, creating a solid cross-linked compound in the areas exposed to high intensity light. Both the front and the back of the flexographic plate are subjected to high intensity exposure. Exposing the back of the flexographic plate to high intensity light causes the back of the plate to solidify to about one half of the total depth of the flexographic plate. This creates a solid backing area or “floor” for the flexographic plate. High intensity exposure of the front of the masked flexographic plate, sometimes referred to as main exposure, results in the cross-linking or curing of those portions of the flexographic plate exposed by the image mask. Areas of the flexographic plate covered by the image mask are not exposed to the high intensity light, and the photocurable resin material in these areas remains in the non-solid, uncured photocurable state.

Following exposure of both the front and back of flexographic plate (which may be performed in any order), the next step is to remove the remaining uncured photocurable resin material from the front of the flexographic plate. This can be done either with a “wet” process which makes use of solvents and brushes to loosen and remove the uncured photocurable resin material, or by means of a “dry” process that employs thermal processing to heat (and partially liquefy) the remaining uncured photocurable resin material, which is removed from the flexographic plate by an absorbent material known as “blotter”. A well-known “dry” process is taught by the Cohen patent (U.S. Pat. No. 3,264,103), which employs a flat iron and filter paper to remove uncured photocurable resin material. Thermal processing of flexographic plates is more desirable than conventional wet processes, because it does not require the use of solvents such as volatile organic compounds (VOCs), which are hazardous and difficult to dispose safely. Also, thermal processing does not require extended drying times necessary to wet processes.

Following removal of the remaining uncured photocurable resin material, the following step is to once again expose the flexographic plate to high intensity light in what is known as post-processing exposure, which ensures that all remaining uncured photocurable resin material is cross-linked or cured. Following post-processing exposure, the surface of the photographic plate is exposed to short wavelength (less than 270 nanometers) UV light to insure the plate has a hard non-tacky surface, which is known as “detackification”.

In the conventional process, great care must be taken between each of the above steps, which are performed at separate stations. Flexographic plates are easily scratched or otherwise blemished in a way that renders useless the image represented on the plate. Flexographic plates are expensive, and losing plates due to corruption resulting from handling is therefore quite undesirable. It would therefore be beneficial if flexographic plates could be processed at a single station. Other improvements in the steps of the process would also be beneficial.

### BRIEF SUMMARY OF THE INVENTION

The present invention provides a system and method of exposing, thermally processing, and post-processing a flexographic plate at a single workstation. In one embodiment, the system includes a workstation for receiving and holding a flexographic plate, an exposure light system, and a thermal processing system. The exposure light system provides high intensity UV light for curing the exposed photocurable material on the flexographic plate. The thermal processing system provides thermal energy to the surface of the flexographic plate, which causes the uncured photocurable material to liquefy. Absorbent material supplied between a heated element and the flexographic plate removes the uncured liquefied photocurable material.

In another embodiment the system and method of exposing, thermally processing, and post-processing a flexographic plate includes a gantry system that includes a main exposure assembly, a pre-heater assembly, a thermal processing assembly, and a germicidal detack lamp assembly. The gantry system moves each of the attached assemblies over the flexographic plate as required to expose, thermally process, and post-process the flexographic plate located on the workstation.

### BRIEF DESCRIPTION OF THE DRAWINGS

FIGS. 1A and 1B are side view diagrams of a first embodiment of a flexographic plate exposure/thermal processing/post-processing system of the present invention.

FIGS. 2A and 2B are side view diagrams of a second embodiment of a flexographic plate exposure/thermal processing/post-processing system of the present invention.

FIG. 3 is a cross-sectional view of the heated element used in systems shown in FIGS. 1A, 1B, 2A, and 2B.

FIG. 4 is an exploded view of a thermal processing assembly.

FIGS. 5A-5C are side view diagrams of several exemplary embodiments of a heated element used in the systems shown in FIGS. 1A, 1B, 2A and 2B.

FIG. 6 is a flow chart of the steps used in processing a flexographic plate using the exposure/thermal processing/post-processing system of the present invention.

### DETAILED DESCRIPTION

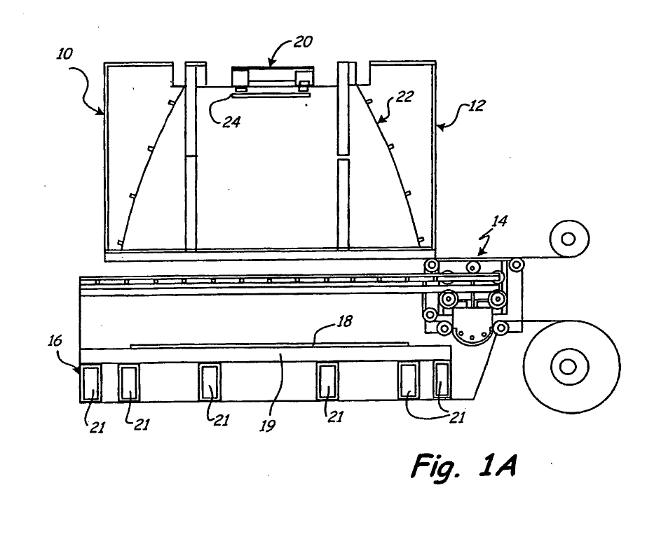

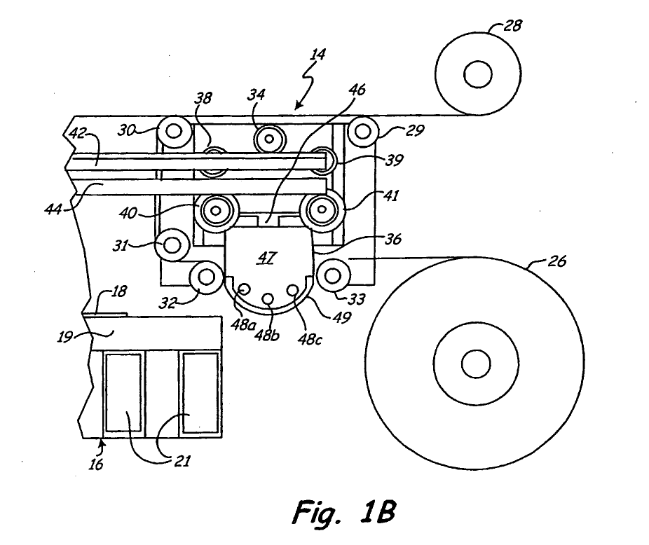

FIG. 1A shows an exemplary embodiment of flexographic plate exposure/processing/post-processing system 10 (“flexographic system 10”) of the present invention. Flexographic system 10 provides a single work station for exposing and curing the photocurable material of flexographic plate 18, removing excess uncured photocurable material through a thermal processing step, and post-processing (including detack) of the flexographic plate.

Flexographic system 10 includes exposure light system 12, thermal processing system 14, and work area 16. In this embodiment, flexographic plate 18 is laid flat on work area 16, which includes support plate 19 and support posts 21. Clamps (not shown) secure flexographic plate 18 to support plate 19. In one exemplary embodiment, support plate 19 regulates the temperature of the non-image (bottom side) of flexographic plate 18 during the thermal processing stages. In this exemplary embodiment, a plurality of water filled channels or tubes (not shown) are included within support plate 19, allowing the temperature of support plate 19 (and thus the non-image side of flexographic plate 18) to be controlled by heating or cooling the water being pumped through the tubing. Maintaining the non-image side of the flexographic plate at a desired temperature prevents uneven thermal expansion of the flexographic plate.

In another exemplary embodiment, a conformal thermally conductive cushioned surface (not shown) is located between flexographic plate 18 and support plate 19, creating a cushioned surface to support flexographic plate 18. The conformal cushioned surface provides additional support that protects the flexographic plate from damage during the exposure/thermal processing/post-processing stages. The thermally conductive cushioned surface also conducts heat away from the non-image side of flexographic plate 18.

As shown in FIG. 1A, exposure light system 12 includes light source 20, reflector 22, and filter 24. In one embodiment, exposure light system 12 is implemented as described in U.S. Pat. No. 6,700,598, assigned to Cortron Corporation and incorporated by reference herein. Light source 20 is a liquid cooled light source providing ultraviolet (UV) light to flexographic plate 18 located on work area 16. Reflector 22 ensures uniform application of UV light to flexographic plate 18. Filter 24 allows exposure light system 12 to be used in more than one capacity. For instance, during main exposure of flexographic plate 18 to cure the exposed photocurable material (creating a hardened cross-linked compound), UV light having a wavelength between 365 to 400 nanometers is desired. Therefore filter 24 is adjusted to remove light falling outside of this desired wavelength. During a later step known as “detackification”, UV light having a wavelength of less than 267 nanometers is desired to further harden the cured or cross-linked compound portions of flexographic plate 18. In this case, filter 24 is adjusted such that light having a wavelength greater than 267 nanometers is removed. In one embodiment, adjustment of filter 24 is done manually by replacing a filter plate (not shown) located within filter 24. In another embodiment, the filter plate is automatically adjusted based on the wavelength desired.

After main exposure of flexographic plate 18 to UV light, in which the exposed areas of the photocurable material are cured and solidified, thermal processing system 14 is used to remove the remaining excess photocurable material (which is uncured and gel-like). Thermal processing system 14 transfers thermal energy to the surface of flexographic plate 18, causing only the surface of the remaining photocurable material to become more viscous. Thermal processing system 14 is controlled to move over the surface of flexographic plate 18 as an absorbent material known as “blotter” is pulled between the thermal processing system 14 and the surface of flexographic plate 18, removing the viscous photocurable material.

FIG. 1B shows a detailed side view of the components included in thermal processing system 14. Thermal processing system 14 includes supply roll 26, take-up roll 28, a number of absorbent material rollers 29, 30, 31, 32, and 33, gear drive 34, heated element 36, top rollers 38 and 39, bottom rollers 40 and 41, rack 42, rail 44, and press device 46. Gear drive 34, top rollers 38 and 39, bottom rollers 40 and 41, rack 42, and rail 44 form a gantry system that allows heated element 36 to be moved over flexographic plate 18. Gear drive 34 uses rack 42 in a rack and pinion system to move thermal processing system 14 longitudinally along rail 44. Thermal processing system may also be moved laterally (into and out of the page) to process flexographic plates with a width greater than the width of heated element 36. Top roller 38 and 39 support the weight of thermal processing system 14 as well as guide thermal processing system 14 along rail 44. Bottom rollers 40 and 41 secure thermal processing system 14 to rail 44, as well as guide thermal processing system 14 along rail 44.

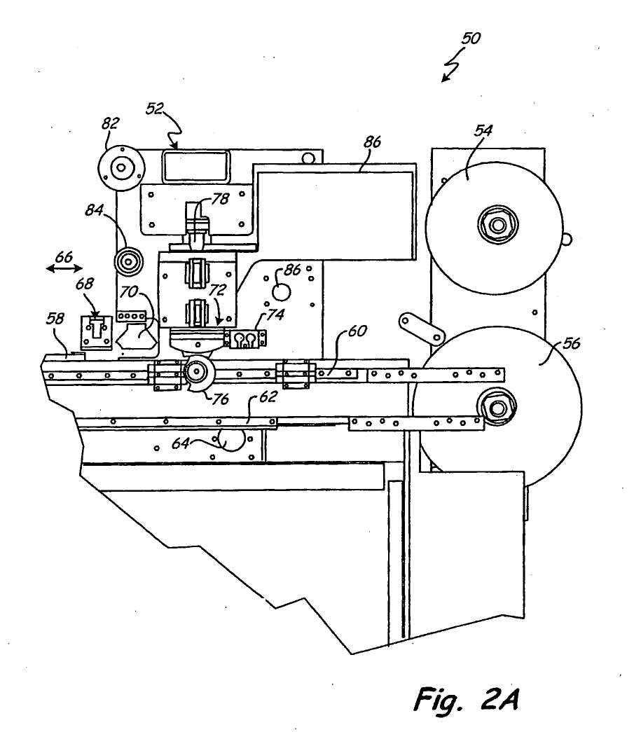

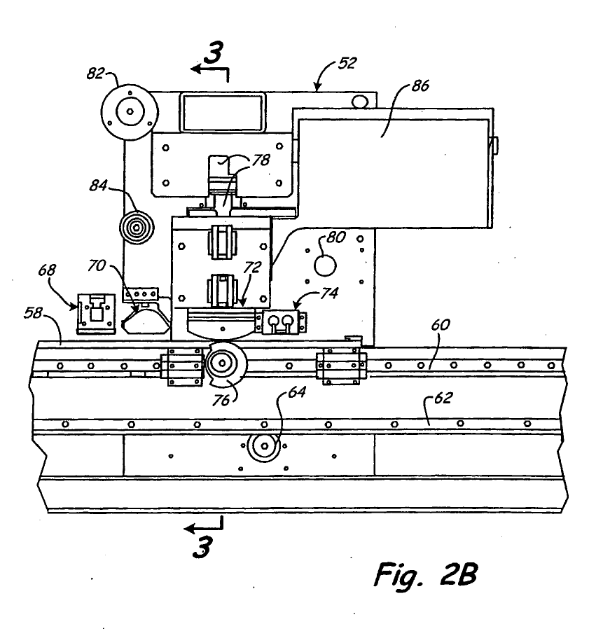

In general, press device 46 causes heated element 36 to be pressed against flexographic plate 18. In one embodiment, press device 46 is a direct acting large displacement cylinder that is either hydraulic or pneumatic. In one embodiment, the pressure generated by press device 46 is regulated by a cam (shown with respect to FIG. 2A) that precisely control the height of heated element 36 with respect to flexographic plate 18. Heat generated within heated element 36 is transferred to flexographic plate 18, which partially liquefies the non-cured photocurable material. Absorbent material supplied by supply roll 26 is pressed between heated element 36 and flexographic plate 18, causing the partially liquefied non-cured photocurable material to be removed from the surface of flexographic plate 18. The gantry system moves heated element along the surface of flexographic plate 18 until all absorbent material has been removed.

Absorbent material or blotter is wound around supply roll 26, and threaded in a serpentine path determined by the location of absorbent material rollers 29, 30, 31, and 32, to take-up roller 28. Absorbent material roller 31 is known as a “capstan” roller, which applies torque to the absorbent material to continually pull absorbent material from supply roll 26 across heated element 36 during thermal processing. To maintain tension on the absorbent material, supply roll 26 may also include an overdrive unit (not shown) that is controllable to create the desired amount of tension. In another embodiment the overdrive unit may be replaced by a back tensioner (not shown) that may also be employed to provide the requisite amount of tension to the absorbent material. Absorbent material is pulled across the portion of heated element 36 facing flexographic plate 18 to continually provide new absorbent material to the surface of flexographic plate 18 being thermally processed. In one exemplary embodiment, the absorbent material pulled across heated element 36 has a width greater than the width of heated element 36, resulting in the absorbent material overlapping the sides of heated element 36. Providing absorbent material with a width greater than the width of heated element 36 can result in improved guidance of the absorbent material over heated element 36. The wider absorbent material can also act to ensure heated element 36 is kept clean, i.e., it prevents heated element 36 from coming into contact with the gel-like photocurable material being removed from flexographic plate 18. Thus, the absorbent material continually wipes both the image side of flexographic plate 18 and heated element 36, providing a self-cleaning mechanism to prevent removed photocurable material from adhering to heated element 36.

As shown in FIG. 1B, heated element 36 includes rigid portion 47, heaters 48a, 48b, and 48c (collectively, “heaters 48”), and cushioned layer 49. Heaters 48 run longitudinally along the length of heated element 36. Depending on the application, heaters may be implemented with either tubular, cartridge, or ribbon heaters. Cartridge heaters and ribbon heaters are controllable to provide “zonal heating.” Zonal heating allows the heat profile of heated element 36 to be varied as desired. For instance, a potential problem with heated elements is the decrease of thermal energy provided by the ends of heated element 36. This temperature variance is often due to the lack of adjacent heater elements at each end of heated element 36. Zonal heating provided by cartridge or ribbon heaters compensate for this problem by generating excess thermal energy at both ends of heated element 36, resulting in a uniform temperature profile being generated along the length of heated element 36. Heat ribbons are discussed in detail with respect to FIG. 4 below. Cartridge heaters may include either a number of individual heating elements, each controllable to generate the desired heat profile, or may contain a single heating element that is custom designed for a particular application, such as by varying the configuration of windings at different regions to generate a desired heat profile. An exemplary cartridge heater for use in heated element 36 is the FireRod® Cartridge Heater manufactured and sold by Watlow Electric Manufacturing Company. The FireRod® Cartridge Heaters can be designed to specification to meet the zonal heating requirements of a particular application.

In other embodiments, the heat profile of heated element 36 (i.e., the distribution of temperature across the width of heated element 36) can be varied to suit a particular application. For instance, in one embodiment, it may be desirable to provide a higher temperature at the leading edge of heated element 36, in order to rapidly increase the temperature of the photocurable material. In this case, heater 48a would be selected or positioned to provide a greater amount of heat to flexographic plate 18. In other embodiments, different heat profiles may be advantageous, in which heaters 48a, 48b, and 48c would be positioned or selected to provide a desired heat profile to flexographic plate 18.

Rigid portion 47 and cushioned layer 49 operate to transfer heat (created by heaters 48) and pressure to flexographic plate 18. Force generated by press assembly 46 is transferred through rigid portion 47 to press cushioned layer 49 into flexographic plate 18. The rigidity inherent within rigid portion 47 results in an equal amount of pressure being applied along the length of heated element 36.

While the inherent rigidity of rigid portion 47 results in consistent pressure being applied between heated element 36 and flexographic plate 18, cushioned layer 49 results in the absorbent material being pressed in between the cured cross-linked compound regions to provide better contact, and there better absorption of the remaining uncured photocurable material. In one embodiment, cushioned layer 49 is made of a low durometer silicon rubber. Physical properties of cushioned layer 49 are selected based on the properties of the flexographic plate 18 being processed. The durometer and thickness of cushioned layer 49 can be varied to accommodate different processing depths and plate durometers. A clamp may be used to secure cushioned layer 49 to rigid portion 47. The clamp (along with tension created by the absorbent material) holds cushioned layer 49 securely against rigid portion 47. Because cushioned layer 49 is not fixedly attached to rigid portion 47, cushioned layer 49 may be replaced with a new cushioned layer. For example, in different applications, it may be desirable to use a different thickness and durometer cushioned layer. The present invention allows cushioned layer 49 to be easily updated to accommodate changes in applications.

In other embodiments, cushioned layer 49 includes a heat transfer composition to better transport heat from rigid portion 47 to flexographic plate 18. In yet another embodiment, cushioned layer 49 is coated with a slip coat material formed on the bottom portion of cushioned layer 49. The slip coat material provides a low-resistance surface for the absorbent material, allowing the absorbent material to slide more easily between heated element 36 and flexographic plate 18. In one embodiment, the slip coat is made of glass reinforced teflon.

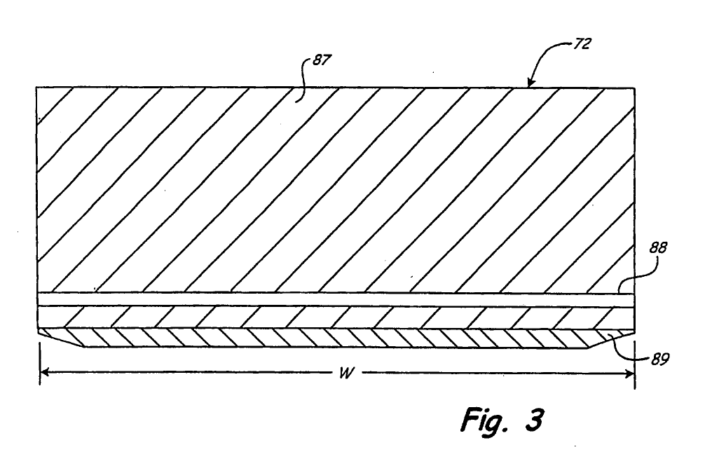

The region of contact between heated element 36 and flexographic plate 18 is known as the “nip”. By altering the profile of heated element 36, the nip geometry can be changed. The nip geometries may be altered depending on the application to provide efficient thermal processing of the flexographic plate. As shown in FIG. 1B, the portion of heated element 36 that contacts flexographic plate 18 (hereinafter, the “bottom” of heated element 36) is cylindrical in shape. In other embodiments, shown in FIGS. 3A-3C, the bottom of heated element 36 is configured to provide various nip configurations. The selected geometry of heated element 36, along with the rigidity of rigid portion 47, allows a controllable amount of pressure to be applied along the bottom of heated element 36, improving the removal of uncured photocurable material.

In other embodiments, the rigidly connected heated element may be replaced with a heated roller. In this embodiment, as the heated roller turns, absorbent material is passed between the heated roller and the flexographic plate, causing uncured photocurable material to be removed from the surface of the flexographic plate. If a heated roller is employed, then either a tubular heater or a cartridge heater should be used to provide the required thermal energy. Once again, the cartridge heater is often advantageous due to the ability to provide zonal heating that results in a constant temperature along heated element 36.

In another aspect of the invention, the orientation of heated element 36 is capable of being fixed at a selected angle with respect to flexographic plate 18. By adjusting the orientation of heated element 36, different parts of cushioned layer 49 can selectively be used to apply pressure between heated element 36 and flexographic plate 18. Periodically readjusting the angle of heated element 36 prevents a single portion of cushioned layer 49 from being worn down, resulting in the entire cushioned layer 49 having to be prematurely replaced. Adjusting the orientation of heated element 36 also allows different nip geometries to be implemented with the same heated element 36.

Therefore, during the thermal processing stage of processing flexographic plate 18, thermal processing system 14 is moved by the gantry system in a longitudinal (i.e., horizontal direction) along flexographic plate 18. Press device 46 applies vertical or downward pressure on heated element 36 to create the necessary amount of pressure between heated element 36 and flexographic plate 18. Thermal energy generated by heaters 48 within heated element 36 causes the remaining excess photocurable material to become more viscous, allowing absorbent material pressed between flexographic plate 18 and heated element 30 to remove the remaining excess, and now viscous, photocurable material.

FIG. 2A shows another exemplary embodiment of flexographic plate exposure/processing/post-processing system 50 (“flexographic system 50”) of the present invention. Flexographic system 50 provides exposure, thermal processing, and post-processing (including detackification) at a single workstation. Flexographic system 50 includes gantry assembly 52, feed roller 54, take-up roller 56, and work area 58. Gantry assembly 52 is mounted on linear bearings 60 and 62. Gear drive 64 connected to rack 62 allows gantry assembly 52 to be moved laterally (i.e., in the directions shown by arrow 66), which allows gantry assembly 52 to operate over the entire surface of a flexographic plate. As shown in FIG. 2A, gantry assembly 52 is shown in a first or home position (i.e., removed from work area 58). In this embodiment, the flexographic plate is laid flat and clamped to work area 58.

Gantry assembly 52 includes main exposure lamp system 68, pre-heater assembly 70, heated element 72, germicidal detackification lamp assembly 74, cam assembly 76, press apparatus 78, absorbent material rollers 80, 82, and 84, and plenum 86. As discussed above, gantry assembly 52 is movable in the direction indicated by arrow 66, allowing each of the devices included in gantry assembly 52 to be moved relative to work area 58. This allows flexographic system 50 to provide exposure, thermal processing, and post-processing of a flexographic plate at a single workstation.

During the exposure step, main exposure lamp 68 provides high intensity UV light to the exposed portions of the flexographic plate. As discussed above, the high intensity light cross-links and cures the exposed portions to create a solid cross-linked compound in the exposed areas. Gantry assembly 52 moves along the surface of the flexographic plate (by way of gear motor 64) as necessary to provide exposure to the entire surface of the flexographic plate. This mode of exposure, in which main exposure lamp 68 moves over different portions of the flexographic plate is known as “scanning”. This is in contrast with the fixed light source described with respect to FIG. 1A, although either embodiment may be employed in a flexographic system that provides exposure, thermal processing and post-processing at a single workstation.

Following exposure of the flexographic plate with main exposure lamp 68, pre-heater 70 and thermal processing assembly 72 (in conjunction with absorbent material rollers 80, 82 and 84) are used to remove uncured, excess photocurable material from the flexographic plate. In one embodiment, pre-heater 70 is a long wave emitter that provides thermal energy only to the image-side of the flexographic place, thus reducing the need to provide cooling to the back or non-image side of the flexographic plate. Feed roller 54 provides absorbent material (i.e., blotter webbing) to gantry assembly 52. Absorbent material, wound in a serpentine path from feed roller 54 to take-up roller 56 through rollers 82, 84, heated element 72 and roller 80, is pressed against the flexographic plate by thermal processing apparatus 72. Additional rollers other than the ones shown in this embodiment may be used to generate the desired tension in the absorbent material as it is passed between thermal processing apparatus and the flexographic plate being processed. Thermal energy provided by pre-heater assembly 70 and heated element 72 is provided to the surface of the flexographic plate, causing uncured photocurable material to partially liquefy. The partially liquefied photocurable material is absorbed by the absorbent material provided between heated element 72 and the flexographic plate.

Following thermal processing of the flexographic plate, main exposure lamp 68 may be used once again to provide post-processing of the flexographic plate. This step ensures the curing of all remaining photocurable material in the flexographic plate. Following exposure using main exposure lamp 68, germicidal detackification lamp assembly 74 generates short-wavelength UV light to detackify the surface of the flexographic plate. As described above, detackification of a flexographic plate insures a hard, non-tacky surface of the flexographic plate. Once again, gantry assembly 52 is moved as required to detackify the entire surface of the flexographic plate.

FIG. 2B shows a detailed view of gantry assembly 52 during the thermal processing stage. As shown, gantry assembly 52 is located over work area 58. Press apparatus 78 causes heated element 72 to be pressed downward against the flexographic plate located on work area 58. As described above, press apparatus 78 is a direct acting large displacement cylinder that may be either hydraulic or pneumatic in nature. Press apparatus provides consistent pressure between heated element 72 and the flexographic plate. The height of heated element 72 relative to the flexographic plate is determined by the position of cam assembly 76. Mechanical stops (not shown) move downward towards cam assembly 76 as press apparatus 78 causes heated element 72 to be pressed downward towards the flexographic plate. When the mechanical stops contact cam assembly 76, heated element 72 is held at the current height relative to the flexographic plate. By rotating cam assembly 76, the desired height of heated element 72 relative to the flexographic plate can be altered. Precise height adjustment of heated element 72 allows the pressure applied to the image side of the flexographic plate to be precisely controlled. Precise height control of heated element 72 improves the efficiency of the system. For example, precise height adjustment of heated element 72 is particularly useful in instances in which several passes are required to fully remove all remaining uncured photocurable material. In each successive pass of heated element 72, the relative height of heated element 72 with respect to the flexographic plate can be lowered to increase the pressure created between heated element 72 and the flexographic plate. This allows for the better quality processing of a flexographic plate as the depth of heated element 72 is adjusted on each successive pass to match the absorbancy of the absorbent material.

Gantry assembly 52 further includes plenum 86 that is used to capture, contain, and filter effluent material generated in the thermal processing of the flexographic plate. Within plenum 86 is a number of charcoal filters that act to filter harmful components of the effluent material. In one embodiment, an air/vacuum generator is used to create a negative pressure differential between the environment within plenum 86 and the outside environment. This forces the captured effluent through the charcoal filters. After passing through the charcoal filters, the filtered air exits plenum 86.

FIG. 3 is a cross section of an alternative embodiment of heated element 72 taken along line 3-3 as shown in FIG. 2B. Heated element 72 includes rigid portion 87, at least one cartridge heater 88 located within rigid portion 87, and cushioned layer 89. In this embodiment, cushioned layer 89 has a tapered edge at both the left and right edge of heated element 72. The tapered edge provides a graduation of pressure applied from heated element 88 to a flexographic plate. The tapered edge is particularly useful in embodiments that require heated element 72 to be moved laterally in a stepped process in order the process a flexographic plate with a width greater than the width W of heated element 72. After processing a first longitudinal section of a flexographic plate, heated element 72 is moved laterally to process a second longitudinal section of the flexographic plate. Overlapping the longitudinal sections processed by heated element 72 (i.e., the tapered edged portions) results in consistent removal of uncured photocurable material along each longitudinal section.

FIG. 4 shows an exploded view of heated element 74. It should be noted that thermal processing assembly 74 as shown in FIG. 4 may also be used in conjunction with flexographic system 10 shown in FIGS. 1A and 1B, replacing the cylindrical or cartridge type heaters shown in that embodiment. Thermal processing assembly 72 includes mounting base 90, insulating layer 92, clamp plate 94, first U-shaped heating ribbon 96a and second U-shaped heating ribbon 96b, center heating ribbon 98 (collectively, “the heating ribbons”), and anvil element 100 having slots for each heating ribbon.

Mounting base 90 connects thermal processing assembly to press assembly 78. Insulating layer 92 is placed between mounting base 90 and clamp plate 94. Insulating layer 92 forces the heat generated by the heating ribbons to be directed downward through anvil element 100 to the flexographic plate. Clamp plate 94 provides means for securing and holding the heating ribbons within anvil element 100. Typically, mounting base 90, insulating layer 92, clamp plate 94, and anvil element 100 are secured together with bolts or screws (or equivalent hardware). This component-based construction of thermal processing apparatus (as opposed to casted equipment which cannot be disassembled) allows a service technician to easily replace worn or damaged components (such as heating ribbons).

First U-shaped heating ribbon 96a and second U-shaped heating ribbon 96b, along with center heating ribbon 98 fit within slots created in anvil element 100. Center heating ribbon 98 extends along the entire length of anvil element 100. First U-shaped heating ribbon 96 provides additional heating to the near side of anvil element 100, while second U-shaped heating ribbon 98 provides additional heating to the far side of anvil element 100. Each heating ribbon has leads that are connected to a controller, allowing the power provided to each ribbon heater to be varied depending on the application. For instance, a typical problem in heating elements is the uneven distribution of temperature at the ends of the heating elements (due in part to the increased surface area at the end of the heating elements). By applying additional energy to U-shaped heating ribbons 96a and 96b, the temperature along the length of anvil element 100 may be maintained at a constant level. To ensure that the uncured photocurable material is heated to a liquefied state, it is important for the heating ribbons to provide uniform heat along the entire length of anvil element 100. In one embodiment, a controller responsible for the energy provided to each heating ribbon is a PID controller, capable of precisely controlling the temperature along the bottom of anvil element 100.

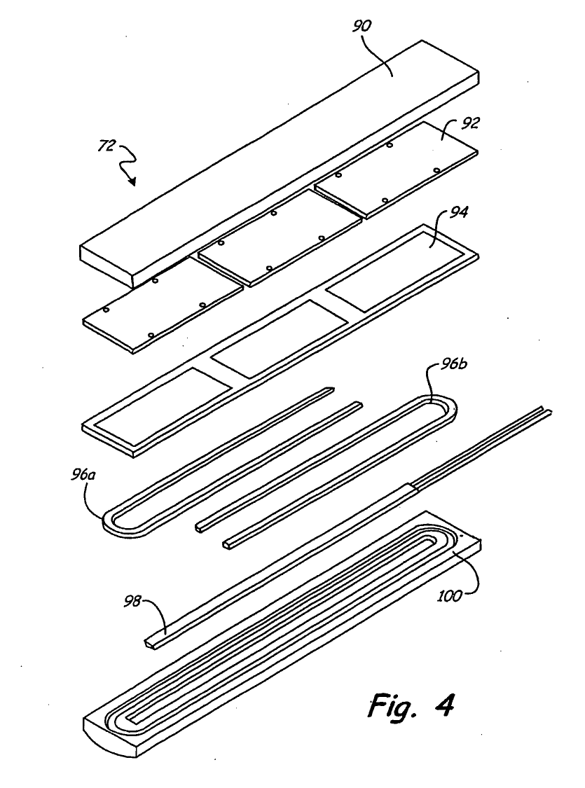

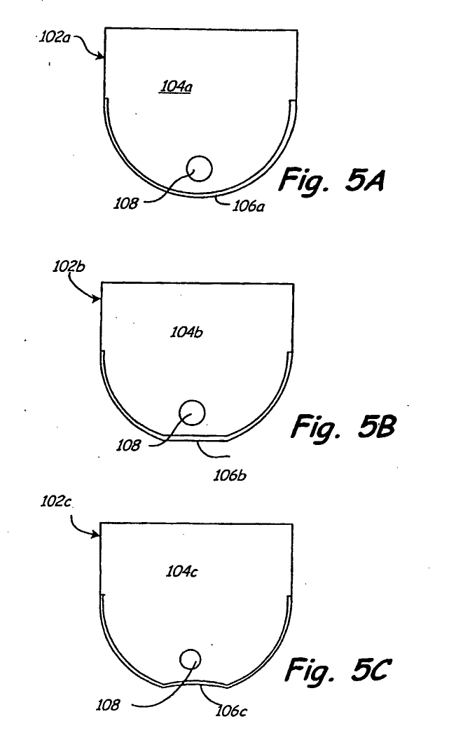

FIGS. 5A-5C shows side views of three exemplary embodiments of heated elements 102a-102c highlighting the nip geometries (bottom side) that may be employed. Each of the heated elements 102a-102c shown in FIGS. 5A-5C may be employed in the systems described with respect to FIGS. 1A, 1B, 2A, and 2B. The possible configurations of heated elements is not limited to the exemplary embodiments shown in FIGS. 5A-5C. Each configuration shown in FIGS. 5A-5C provides a different nip profile, or contact geometry between heated elements 102a-102c and a flexographic plate. The ability to vary the nip profile allows the thermal processing system of the present invention to accommodate different processing depths, different plate durometers and different viscous thermal needs. The heated elements 102a-102c are described with special emphasis placed on the nip geometry, and it should be noted that the structure of each of the heated elements 102a-102c may be similar to the exploded view shown in FIG. 4 of heated element 72, which included the use of ribbons heaters. However, the heated elements 102a-102c shown in these embodiments make use of a cartridge heater to achieve the desired heat profile. As discussed above, cartridge heaters may contain multiple controllable heating elements that allow the cartridge heater to provide zonal heating.

FIG. 5A shows an embodiment in which heated element 102a (including rigid portion 104a and cushioned layer 106a) is formed with a convex bottom (as shown in FIGS. 1A, 1B, 2A and 2B). Cartridge heater 108 is positioned a set distance from the bottom portion of heated element 90a, following the convex curve of heated element 102a.

FIG. 5B shows an embodiment in which heated element 102b (including rigid portion 104b and cushioned layer 106b) is formed with a flat bottom. This configuration provides a larger surface for contacting a flexographic plate. In this embodiment, cartridge heater 108 is positioned a set distance from the bottom portion of heated element 102b, following the flat portion of heated element 102b.

FIG. 5C shows an embodiment in which heated element 102c (including rigid portion 104c and cushioned layer 106c) is formed with a concave bottom. This geometric shape may be particularly useful in applications involving a cylindrical sleeve, in which case the concave shape of heated element 102c can be formed to fit to the shape of the cylindrical sleeve.

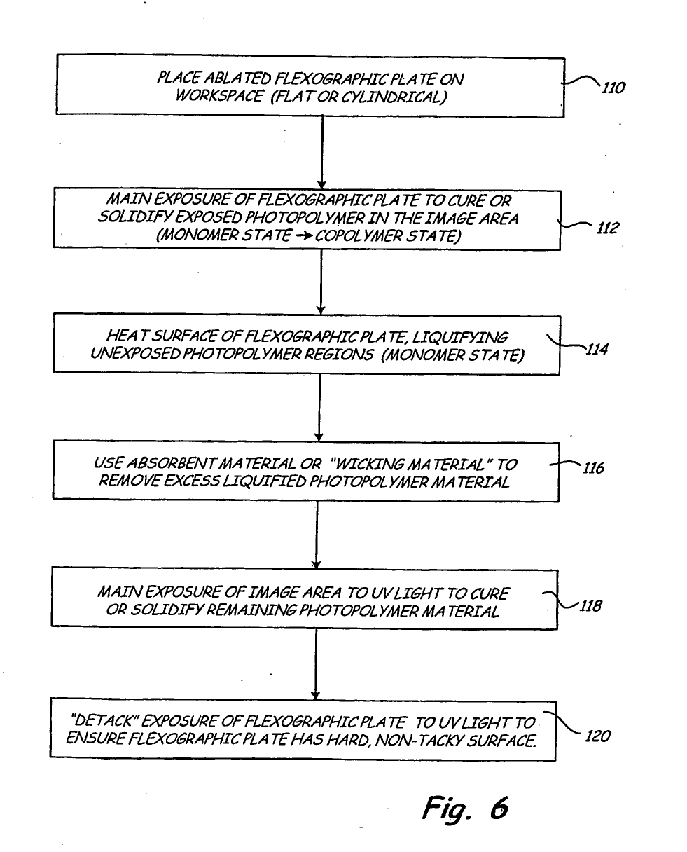

FIG. 6 is a flowchart illustrating the steps performed by a flexographic processing system of the present invention. At step 110 a masked or ablated flexographic plate is placed on a workspace (either flat or cylindrical). Clamps or similar clamping devices are used to secure the flexographic plate to the workspace. For example, work area 16 as shown in FIG. 1A is an exemplary embodiment of the workspace used in step 86.

At step 112 the flexographic plate is exposed to UV light in what is called “main exposure”. FIGS. 1A and 1B illustrate one method of exposing the flexographic plate to UV light using a light exposure system that is stationary above the workspace. FIGS. 2A and 2B illustrate another method of exposing the flexographic plate to UV light, in which a main exposure lamp is mounted on a gantry assembly that allows the main exposure lamp to scan over the flexographic plate. Main exposure causes exposed areas of the photocurable material to be cured, converting the photocurable material into a cross-linked compound that is rigid and solid. Areas of the flexographic plate not exposed during the main exposure step remain in an uncured, gel-like state.

At step 114 a thermal process is performed to remove the remaining uncured photocurable material. Heat is applied to the surface of the flexographic plate using a heated element, liquefying the uncured photocurable material. At step 116, absorbent material, known as “blotter” or “wicking material” is applied under pressure between the heated element and the flexographic plate as shown in FIGS. 1A, 1B, 2A and 2B to remove the excess remaining uncured photocurable material. At step 118, the flexographic plate is again exposed to UV light in a post-processing step. Applying UV light to the flexographic plate a second time cures all remaining photocurable material. This step would be performed by light exposure system 12 as shown in FIG. 1A, or main exposure lamp system 68 as shown in FIGS. 2A and 2B. At step 120, the flexographic plate is again exposed to UV light, albeit shorter wavelength UV light in a process known as “detack.” Exposing the flexographic plate to light having wavelengths less than 267 nanometers causes a hardening of the already cured cross-linked compound, ensuring that the flexographic plate has a hard, non-tacky surface. Exposure light system 12 having light source 20 and interchangeable filter 24 as shown in FIG. 1 is one exemplary embodiment capable of performing step 120. Germicidal detack lamp assembly 74 connected to gantry assembly 52 as shown in FIGS. 2A and 2B is another exemplary embodiment of an apparatus capable of performing this step.

Therefore, a flexographic plate processing system has been described, wherein exposure and thermal processing of a flexographic plate are performed at a single workstation. By providing exposure and thermal processing at a single workstation the number of flexographic plates damaged during transition between workstations is reduced. Thermal processing of the flexographic plate is performed with a heated element, mounted to a press device for generating pressure between the heated element and the flexographic plate. The press device maintains consistent pressure between the heated element and the flexographic plate. At least one heater (either tubular, cartridge, or ribbon type) located within the heated element provides the necessary thermal energy to at least partially liquefy the uncured photocurable material on the flexographic plate. The heated element uses zonal heating (either through multiple heaters, or by configuring the placement of windings) to ensure uniform heat is supplied by the heated element to the surface of the flexographic plate. By applying uniform pressure and temperature to the surface of the flexographic plate, uncured photocurable material is uniformly removed from the surface of the flexographic plate.

Although the present invention has been described with reference to preferred embodiments, workers skilled in the art will recognize that changes may be made in form and detail without departing from the spirit and scope of the invention.

1. A system for processing a flexographic plate, the system comprising:
a workstation for receiving the flexographic plate;
an exposure light system for providing high intensity UV light to the flexographic plate located on the workstation, wherein the high intensity light cures exposed photocurable material on the flexographic plate; and
a thermal processing system for removing non-cured photocurable material from the flexographic plate located on the workstation.

2. The system of claim 1, wherein the thermal processing system includes:
a heated element non-rotationally mounted to a press device that presses a first surface of the heated element against the flexographic plate; and
a material delivery mechanism for delivering absorbent material to the first surface of the heated element and the flexographic plate.

3. The system of claim 2, wherein the geometry of the first surface of the heated element is either concave, convex or flat in shape.

4. The system of claim 2, wherein the heated element includes:
a rigid portion non-rotationally attached to the press device for transmitting pressure to the flexographic plate;
a cushioned layer removably attached to the rigid portion; and
at least one heater located within the rigid portion for generating thermal energy, wherein thermal energy generated by the heater is transferred to the flexographic plate.

5. The system of claim 2, wherein the heated element includes:
a zonal heater configuration controlled to create a uniform heat profile along a length of the heated element.

6. The system of claim 5, wherein the zonal heater configuration is a cartridge heater that includes:
a first heating element located on a distal end of the heated element;
a second heating element located on a proximal end of the heated element; and
a third heating element located between the first heating element and the second heating element, wherein the first heating element, the second heating element and the third heating element are controllable to provide uniform heating along the length of the heated element.

7. The system of claim 5, wherein the zonal heater configuration is a cartridge heater that includes:
a heating element having a coil winding configuration that provides uniform heating along the length of the heated element.

8. The system of claim 5, wherein the zonal heater configuration comprises:
a first center ribbon heater placed in the center of the heated element;
a first U-shaped ribbon heater placed at a proximate end of the heated element; and
a second U-shaped ribbon heated placed at a distal end of the heated element, wherein a heat profile of the heated element is based on selective application of power to the center ribbon, first U-shaped ribbon, and second U-shaped ribbon.

9. The system of claim 1, further including:
a long-wave emitter for providing thermal energy to the flexographic plate located on the workstation.

10. The system of claim 2, further including:
a gantry assembly mounted to move longitudinally over the workstation, wherein the thermal processing system is mounted on the gantry assembly.

11. The system of claim 10, wherein the exposure light system is mounted to the gantry assembly.

12. The system of claim 10, further including:
a germicidal detack lamp assembly mounted to the gantry assembly, wherein the germicidal lamp assembly provides short wavelength UV light to the first surface of the flexographic plate.

13. The system of claim 1, wherein the workstation includes:
a flat bed for receiving the flexographic plate;
a cushioned section positioned between the flat bed and the flexographic plate; and
a mechanism for securing the flexographic plate to the flat bed.

14. The system of claim 1, wherein the workstation includes:
a plenum having a negative pressure differential with respect to an outside environment; and
at least one filter located within the plenum, wherein the negative pressure differential causes effluent material generated by the thermal processing of a flexographic plate to be forced through the at least one filter.

15. The system of claim 14, wherein the at least one filter is a charcoal filter.

16. The system of claim 14, wherein the workstation includes:
a vacuum generator for generating the negative pressure differential within the plenum.

17. A system for thermally processing a flexographic plate, the system comprising:
a heated element non-rotationally mounted to a press device that presses a first surface of the heated element against an image side of the flexographic plate;
a zonal heating configuration located within the heated element for generating thermal energy within the heated element; and
a material delivery mechanism for delivering absorbent material between the first surface of the heated element and the image side of the flexographic plate.

18. The system of claim 17 wherein the zonal heating configuration employs a cartridge heater, the cartridge heater comprising:
a first heating element located at a distal end of the heated element;
a second heating element located at a proximal end of the heated element; and
a third heating element located between the first heating element and the second heating element, wherein a heat profile of the heated element is controlled by selectively applying power to the first heating element, the second heating element and the third heating element.

19. The system of claim 17 wherein the zonal heating configuration is a cartridge heater, the cartridge heater comprising:
a single heating element having windings configured to provide uniform heating along the length of the heated element.

20. The system of claim 17, wherein the zonal heating configuration is a ribbon heater, comprising:
a first center ribbon heater placed in the center of the heated element;
a first U-shaped ribbon heater placed at a proximate end of the heated element; and
a second U-shaped ribbon heated placed at a distal end of the heated element, wherein a heat profile of the heated element is based on selective application of power to the center ribbon, first U-shaped ribbon, and second U-shaped ribbon.

21. A system for thermally processing a flexographic plate, the system comprising:
a heated element non-rotationally mounted to a large press device that presses a first surface of the heated element against an image side of the flexographic plate;
a material delivery mechanism for delivering absorbent material between the first surface of the heated element and the image side of the flexographic plate; and
a cam assembly for providing feedback to the press device such that the heated element is maintained at a desired height above the flexographic plate.

22. The system of claim 21, wherein the cam assembly is controlled to set the desired height of the heated element.

23. The system of claim 21, wherein the heated element includes:
a first portion non-rotationally mounted to the press device, wherein the first portion is rigid;
a second portion removably attached to the first portion to form the first surface for receiving the absorbent material, wherein force generated by the force generating mechanism is transmitted through the first portion to the second portion, pressing the absorbent material into the flexographic plate; and
at least one heater, wherein the at least one heater provides thermal energy to the first portion, the thermal energy being transmitted to the flexographic plate.

24. The system of claim 23, wherein the second portion is comprised of a low durometer silicon rubber layer.

25. The system of claim 23, wherein the first surface of the heated element includes a glass reinforced teflon slip coat layer.

26. The system of claim 23, wherein the at least one heater is controllable to provide zonal heating for generating uniform heating along a length of the heated element.

27. A system for thermally processing an exposed flexographic plate, the system comprising:
a thermal subsystem for removing non-cured photocurable material from the exposed flexographic plate;
a plenum having a negative pressure differential with respect to an outside environment; and
at least one filter located within the plenum, wherein the negative pressure differential causes effluent material generated by the thermal processing of a flexographic plate to be forced through the at least one filter.

28. The system of claim 27, wherein the thermal subsystem comprises:
a heated element non-rotationally mounted to a press device that presses a first surface of the heated element against the flexographic plate; and
a material delivery mechanism for delivering absorbent material to the first surface of the heated element and the flexographic plate.

29. A system for thermally processing an exposed flexographic plate, the system comprising:
a heated element for applying pressure against the flexographic plate to remove non-cured photocurable material from the exposed flexographic plate, the heated element including a zonal heater configuration controlled to create a uniform heat profile along a length of the heated element; and
a material delivery mechanism for delivering absorbent material between the heated element and the flexographic plate.

30. The system of claim 29, wherein the heated element is non-rotationally mounted to a press device that presses a first surface of the heated element against the flexographic plate.

31. The system of claim 29, wherein zonal heater configuration is a cartridge heater that includes:
a first heating element located on a distal end of the heated element;
a second heating element located on a proximal end of the heated element; and
a third heating element located between the first heating element and the second heating element, wherein the first heating element, the second heating element and the third heating element are controllable to provide uniform heating along the length of the heated element.

32. The system of claim 29, wherein the zonal heater configuration is a cartridge heater that includes:
a heating element having a coil winding configuration that provides uniform heating along the length of the heated element.

33. The system of claim 29, wherein the zonal heater configuration comprises:
a first center ribbon heater placed in the center of the heated element;
a first U-shaped ribbon heater placed at a proximate end of the heated element; and
a second U-shaped ribbon heated placed at a distal end of the heated element, wherein a heat profile of the heated element is based on selective application of power to the center ribbon, first U-shaped ribbon, and second U-shaped ribbon.
